(19) United States
(12) Patent Application Publication
(10) Pub. No.: US 2026/0253201 A1
(43) Pub. Date: Aug. 27, 2026

(54) VIRTUAL DISPENSE FLOW-RATE CALIBRATION AND CONTROL ON FLUID DISPENSING TOOLS

(71) Applicant: TOKYO ELECTRON LIMITED, Tokyo (JP)

(72) Inventors: Sean Patrick BERGLUND, Austin, TX (US); Hiroshi MARUMOTO, Leuven (BE); Michael CARCASI, Leuven (BE); Masashi ENOMOTO, Koshi City (JP); Ihsan SIMMS, Austin, TX (US)

(73) Assignee: TOKYO ELECTRON LIMITED, Tokyo (JP)

(21) Appl. No.: 19/062,297

(22) Filed: Feb. 25, 2025

(51) Int. Cl. G06T 7/00; H01L 21/67

(52) U.S. Cl. CPC G06T 7/001; H10P 72/0604; G06T 2207/30148

(57) ABSTRACT

Aspects of the present disclosure provide a dispense flow-rate calibration and control system. For example, the system can include an image capturing device that is configured to capture on a substrate a first image of a first fluid and a second image of a second fluid dispensed sequentially under a predetermined condition. The system can further include an image analyzer that is coupled to the image capturing device. The image analyzer can be configured to compare the second image and the first image to determine whether a second dispense flow-rate at which the second fluid is dispensed is different from a first dispense flow-rate at which the first fluid is dispensed.

### FIELD OF THE INVENTION

The present disclosure relates to semiconductor processing, and, in particular, to virtual dispense flow-rate calibration and control.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth. A dispenser can be used to dispense a liquid (e.g., chemical) at a certain dispense flow-rate on a rotating wafer, and the liquid can be processed and transformed to a film formed on the wafer.

Differences in actual chemical dispense flow-rate often cause process problems for fluid dispensing tool (e.g., surface preparation system (SPS)) customers, especially differences between SPS tools and wet chambers.

### SUMMARY

Aspects of the present disclosure provide a dispense flow-rate calibration and control system. For example, the system can include an image capturing device that is configured to capture on a substrate a first image of a first fluid and a second image of a second fluid dispensed sequentially under a predetermined condition. The system can further include an image analyzer that is coupled to the image capturing device. The image analyzer can be configured to compare the second image and the first image to determine whether a second dispense flow-rate at which the second fluid is dispensed is different from a first dispense flow-rate at which the first fluid is dispensed.

In an embodiment, the system can further include a fluid dispensing tool that configured to dispense the first fluid and the second fluid, and the image analyzer can be further configured to calibrate the fluid dispensing tool after determining that the second dispense flow-rate is different from the first dispense flow-rate. In another embodiment, the image analyzer can be further configured to generate a first curve based on the first image and a second curve based on the second image, and determine whether the second dispense flow-rate is different from the first dispense flow-rate by comparing the second curve and the first curve, the first curve relates a first feature attribute of the first fluid to the first dispense flow-rate, and the second curve relates a second feature attribute of the second fluid to the second dispense flow-rate.

In some embodiments, the first feature attribute of the first fluid can include a first hydraulic feature of the first fluid, the second feature attribute of the second fluid can include a second hydraulic feature of the second fluid, and the image analyzer can determine whether the second dispense flow-rate is different from the first dispense flow-rate by comparing the second hydraulic feature and the second hydraulic feature.

In various embodiments, the first hydraulic feature of the first fluid can include a first hydraulic jump of the first fluid or a first dry spot on the substrate, the second hydraulic feature of the second fluid can include a second hydraulic jump of the second fluid or a second dry spot on the substrate, and the image analyzer can determine whether the second dispense flow-rate is different from the first dispense flow-rate by comparing the second hydraulic jump and the first hydraulic jump or comparing the second dry spot and the first dry spot.

In various embodiments, the predetermined condition can include an analysis region of the first and second images that overlaps the first and second hydraulic jumps, and the image analyzer can determine whether the second dispense flow-rate is different from the first dispense flow-rate by determining whether a first length of a first arc of the first hydraulic jump within the analysis region is different from a second length of a second arc of the second hydraulic jump within the analysis region.

In an embodiment, the first hydraulic feature of the first fluid can include a first ripple feature of the first fluid, the second hydraulic feature of the second fluid can include a second ripple feature of the second fluid, and the image analyzer can determine whether the second dispense flow-rate is different from the first dispense flow-rate by comparing sizes and/or movements of the first and second ripple features.

In another embodiment, the predetermined condition can include at least one selected from a group consisting of chemical contained in the first and second fluid, surface treatment being performed on the substrate, where the first fluid is dispensed and impinges the substrate, a rotating speed of the substrate, and a range of dispense flow-rates including the first and second dispense flow-rates. For example, the second fluid can be the same as the first fluid. As another example, the second fluid can be different from the first fluid.

Aspects of the present disclosure provide a method for calibrating and controlling dispense flow-rate of a fluid dispensing tool. For example, the method can include capturing on a substrate a first image of a first fluid and a second image of a second fluid dispensed sequentially under a predetermined condition. The method can further include comparing the second image and the first image to determine whether a second dispense flow-rate at which the second fluid is dispensed is different from a first dispense flow-rate at which the first fluid is dispensed.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a schematic diagram of an exemplary dispense flow-rate calibration and control system according to some embodiments of the present disclosure;

FIG. 2 is a flow chart of an exemplary method for calibrating and controlling dispense flow-rate of a fluid dispensing tool according to some embodiments of the present disclosure;

FIGS. 3A-3E show various hydraulic features formed on a substrate as dispense flow-rates change according to some embodiments of the present disclosure;

FIGS. 4A-4F show various hydraulic features formed on a substrate as the location of the dispenser nozzle that dispenses a fluid changes from the center of the substrate to different radial distances according to some embodiments of the present disclosure; and

FIGS. 5A-5E show the arc length of the edge of various hydraulic jumps as dispense flow-rate changes according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Semiconductor manufacturing is a complex process that involves hundreds of process steps performed on a variety of equipment including fluid dispensing (e.g., surface preparation system (SPS)) platforms, which are configured to dispense or spray chemicals onto wafers to clean and etch surface layers. For example, a fluid dispensing tool can be used in a single wafer cleaning process and may incorporate a physical cleaning function featuring dual-fluid spray technology and brushes, thus with a capability to process both wafer sides simultaneously. During SPS processing, the dispense flow-rate can have a significant impact on the within wafer uniformity and wafer-to-wafer repeatability of the surface layer being cleaned or etched.

Image capturing (or video recording) and image (or video frame) analysis has been widely adopted in various manufacturing industries for quality control, fault detection, and preventative maintenance. However, its potential has not been fully realized for SPS processing. The present invention proposes the use of image capturing (or video recording) and image (or video frame) analysis of hydraulic features present during SPS process, e.g., hydraulic jumps of the fluid dispensed by a fluid dispensing tool and flowing on a rotating wafer and a dry spot formed in the center of a rotating wafer, to calibrate and monitor the dispense flow-rate of the fluid dispensing tool in real-time.

According to the present disclosure, methods and systems of calibrating and monitoring dispense flow-rates of fluid dispensing tools are proposed. Image capturing (or video recording) and image (or video frame) analysis methods allow for automated calibration of dispense flow-rate based on correlation to direct physical measurements of volumetric flow-rate.

When the actual dispense flow-rate of a fluid dispensing tool drifts away from the value established during calibration (e.g., a calibration dispense flow-rate), the drifting dispense flow-rate can negatively impact surface layer properties such as thin film thickness, potentially resulting in lower end-of-line (EOL) yield. To prevent this, a fluid dispensing tool must be taken down regularly for preventative maintenance to re-calibrate the dispense flow-rate. In cases where a larger than expected drifting in actual dispense flow-rate is suspected, the fluid dispensing tool might be taken down for unscheduled maintenance. During maintenance, the actual dispense flow-rate is measured manually by engineers using analytical chemistry apparatus. This takes time resulting in lost production. It also poses safety risks to the personnel performing the maintenance such as working at height and exposure to hazardous process chemicals such as hydrofluoric acid. According to the present disclosure, differences in actual chemical dispense flow-rates are automatically detected, and the dispense flow-rate is calibrated by image analysis rather than manual calibration by engineers.

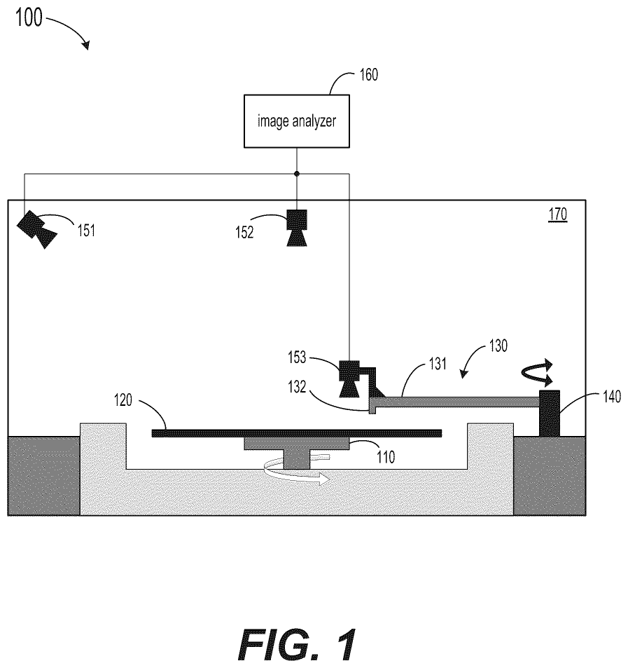

FIG. 1 is a schematic diagram of an exemplary dispense flow-rate calibration and control system 100 according to some embodiments of the present disclosure. The system 100 can solve the problem of drifting flow-rate of a fluid dispensing tool by continuously monitoring a SPS process performed by the fluid dispensing tool using an image capturing (or video recording) device along with image (or video frame) analysis algorithms to estimate the actual dispense flow-rate based on the visual appearance (e.g., the images or video frames) of hydraulic features (e.g., hydraulic jumps and dry spots) present on the surface of the wafer.

In an embodiment, the system 100 can include a wafer holder (or substrate holder) 110 that is installed in a processing chamber 170, for a wafer (or a substrate) 120 to be placed on. The wafer holder 110 can rotate, and so does the wafer 120 accordingly, around an axis. In another embodiment, the system 100 can further include a fluid dispensing tool (which may be included in a SPS tool) 130 that is configured to dispense or spray liquid, e.g., chemicals, on the wafer 120, which is rotating. In some embodiments, the fluid dispensing tool 130 can be attached to a driving device 140 that can drive the fluid dispensing tool 130, e.g., rotating a certain angle, moving linearly, etc., for the fluid dispensing tool 130 to dispense the fluid at different positions on the wafer 120. In various embodiments, the system 100 can further include one or more image capturing (or video recording) devices, e.g., first through third cameras (e.g., video cameras) 151-153, that are disposed at different places to view different hydraulic features formed by the fluid dispensed by the fluid dispensing tool 130 on the rotating wafer 120 during SPS processing and capture the images of the fluid from different angles. For example, the first camera 151 can be disposed in a top corner of the processing chamber 170 to view the fluid dispensed on the wafer 120 and capture the image of the fluid from an inclined angle, the second camera 152 can be disposed above or over (e.g., the center of) the wafer 120 (e.g., on the ceiling of the processing chamber 170) to capture the image of the whole fluid dispensed on the wafer 120, and the third camera 153 can be disposed on or attached to the fluid dispensing tool 130 (e.g., attached to a dispenser arm 131 of the fluid dispensing tool 130) to capture the image of a certain region (e.g., in the proximity of a dispenser nozzle 132) of the fluid dispensed on the wafer 120. The camera resolution of the first through third cameras 151-153 can vary from low (VGA 640×480) to high (4K UHD 3840×2160) along with the lens magnification depending on the precision required for resolving hydraulic features. Higher camera resolution allows for higher sensitivity. Camera frame rate should be high enough to capture the necessary number of video frames during a dispense to average out fluctuations in hydraulic features.

In an embodiment, the system 100 can further includes an image analyzer 160, e.g., a processor or an algorithm, that is coupled, in wired or wireless way, to the first through third cameras 151-153 and the fluid dispensing tool 130 to analyze and compare the actual images that the first through third cameras 151-153 capture currently for the fluid dispensed by the fluid dispensing tool 130, which may be used for a predetermined period of time after it is fully calibrated, with calibration (or reference) images that the first through third cameras 151-153 capture previously for the fluid dispensed by the fluid dispensing tool 130 that is fully calibrated and is accurate, to determine whether the fluid dispensing tool 130 is still accurate or needs to be calibrated, for example, by determining if the flow-rate setpoint matches the calibration curve (or calibration datasets), and how the fluid dispensing tool 130 will be calibrated. In some embodiments, the image analyzer 160 can be further configured to generate a set of calibration (or reference) curves based on the previously captured calibration images and a set of actual curves (or actual datasets) based on the currently captured actual images, and compare the actual curves with the calibration curves to determine whether the fluid dispensing tool 130 is accurate or needs to be calibrated and how the fluid dispensing tool 130 will be calibrated. In various embodiments, control charts, on which the hourly status may be arranged, can be used to judge the occurrence of abnormalities based on the presence of data that differs from the conventional trend or deviates from the control limit line (e.g., historical trend of image analysis metric). For example, Western Electric rules can be used for detection of signals, e.g., out-of-control or non-random conditions on control charts.

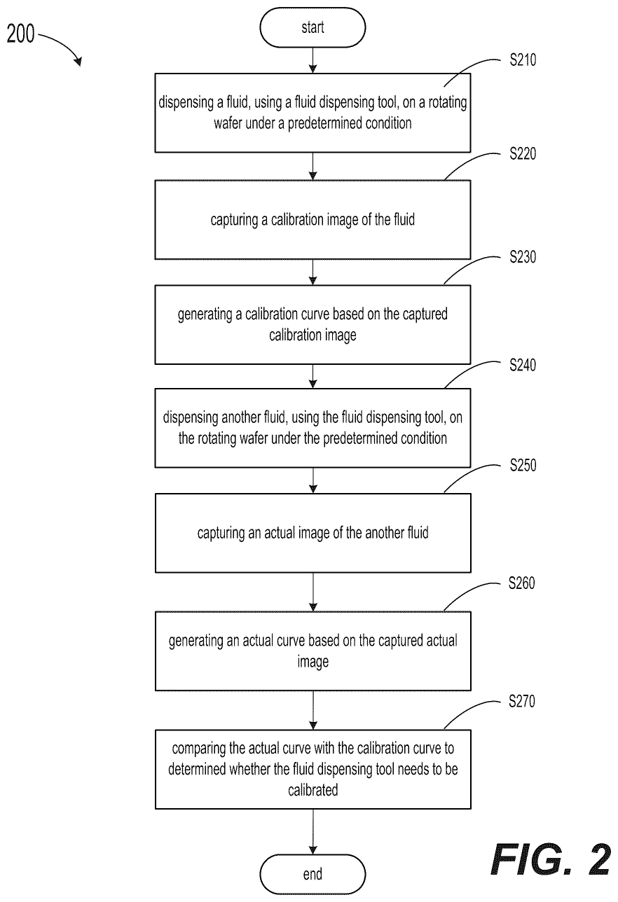

FIG. 2 is a flow chart of an exemplary method 200 for calibrating and controlling dispense flow-rate of a fluid dispensing tool, e.g., the fluid dispensing tool 130, according to some embodiments of the present disclosure. In various embodiments, some of the steps of the method 200 shown can be performed concurrently or in a different order than shown, can be substituted by other method steps, or can be omitted. Additional method steps can also be performed as desired. Aspects of the method 200 can be implemented by a dispense flow-rate calibration and control system such as the dispense flow-rate calibration and control system 100 illustrated in and described with respect to FIG. 1. The method 200 starts with step S210, at which a fluid can be dispensed on a wafer that may be rotating under a predetermined condition (or golden condition), to test the wafer with a preferred surface treatment depending on chemical being dispensed, optimal dispenser arm position to discern hydraulic features, ideal rotation speed (e.g., rotations per minute (RPM)), and range of flow-rates that includes the target flow-rate. For example, a fluid dispensing tool, e.g., the fluid dispensing tool 130, which is fully calibrated and is accurate, can be used to dispense a fluid (e.g., a first fluid) on a rotating wafer, e.g., the wafer 120, that is rotated by a wafer holder, e.g., the wafer holder 110. As another example, the driving device 140 can be used to rotate a certain angle or move linearly, for the fluid dispensing tool 130 to dispense the fluid at a certain position on the wafer 120. In an embodiment, the predetermined condition can include chemicals being dispensed, the surface treatment being performed on (e.g., the surface of) the wafer 120 (e.g., hydrophilic, hydrophobic, etc.), the location of the dispenser arm 131 (e.g., the radial distance of the dispenser arm 131 with respect to the wafer 120) (i.e., where the fluid is dispensed and impinges the wafer 120), the rotating speed of the wafer 120, the range of dispense flow-rates including a target flow-rate, fixed analysis regions (e.g., X, Y coordinate in the image (e.g., each view frame), and so on. The method 200 can proceed to step S220.

At step S220, the calibration image (or video frame) of the fluid can be captured. For example, one or more of the first through third cameras 151-153 can be used to capture the calibration image of the fluid that is dispensed on the wafer 120 by the fluid dispensing tool 130 under the predetermined condition. The method 200 can proceed to step S230.

At step S230, a calibration curve (or calibration datasets) can be generated based on the captured calibration image. For example, the image analyzer 160 can be used to generate a calibration curve based on the captured calibration image of the fluid, which is dispensed on the wafer 120 by the fluid dispensing tool 130, which is fully calibrated and is accurate, under the predetermined condition. In an embodiment, from the predetermined condition the calibration curve can correlate one or more feature attributes (e.g., the size of a hydraulic jump feature and the dry spot vs. direct physical measurement of dispense flow-rate) to the dispense flow-rate of the fluid dispensing tool 130.

For example, the feature attributes can include the size and/or shape of a hydraulic feature (e.g., a hydraulic jump) of the fluid and a dry spot formed on the wafer 120, which may depend on the predetermined condition, e.g., the chemical being dispensed, the surface treatment being performed on the surface of the wafer 120, the location of the dispenser arm 131, the rotating speed of the wafer 120, the range of dispense flow-rates including a target flow-rate, fixed analysis regions (e.g., X, Y coordinate in the image (e.g., each video frame)), and so on. In an embodiment, steps S210 to S230 can be repeated a predetermined number of times under various conditions in order to generate a set of calibration curves. The method 200 can proceed to step S240.

At step S240, another fluid (e.g., a second fluid) can be dispensed on the rotating wafer 120 under the predetermined condition. In an embodiment, the fluid and the another fluid can be dispensed during two separate processes. For example, the fluid and the another fluid can be different and dispensed during two separate processes. In another embodiment, the fluid and the another fluid can be dispensed during the same process and the another fluid can be dispensed at a later point in time. For example, the fluid dispensing tool 130, which is used for a predetermined period of time and maybe inaccurate, can be used to dispense the another fluid on the wafer 120 under the same condition, i.e., the predetermined condition, as that under which the fluid dispensing tool 130, which was fully calibrated and was still accurate, dispenses the fluid previously. In an embodiment, the another fluid can be the same as the fluid dispensed at step S210. In various embodiments, the fluid and the another fluid can actually be from the same chemical tank and process line. The method 200 can proceed to step S250.

At step S250, the actual image (or video frame) of the another fluid can be captured currently (or in real-time). For example, one or more of the first through third cameras 151-153 can capture in real-time the actual image of the fluid that is dispensed on the wafer 120 by the fluid dispensing tool 130 currently under the predetermined condition. The method 200 can proceed to step S260.

At step S260, an actual curve (or actual datasets) can be generated based on the captured actual image. For example, the image analyzer 160 can generate the actual curve based on the captured actual image of the fluid, which is dispensed on the wafer 120 by the fluid dispensing tool 130 currently under the predetermined condition. In an embodiment, the actual curve can also correlate one or more feature attributes to the dispense flow-rate of the fluid dispensing tool 130. The method 200 can proceed to step S270.

At steps S270, the actual curve can be compared with the calibration curve to determine whether the fluid dispensing tool 130 needs to be calibrated and how the fluid dispensing tool 130 will be calibrated. For example, the image analyzer 160 can be used to compare the actual curve and the calibration curve and determine whether the fluid dispensing tool 130 needs to be calibrated and how the fluid dispensing tool 130 will be calibrated. In some embodiments, the actual image generated at step S220 can be compared with the calibration image generated at step S250 to determine whether the fluid dispensing tool 130 needs to be calibrated and how the fluid dispensing tool 130 will be calibrated. When all factors (e.g., the predetermined condition) besides the dispense flow-rate are known or constant, then changes in the size and shape of the hydraulic jump and the dry spot can be directly correlated with dispense flow-rate. In some embodiments, steps S240 to S270 can be continually repeated to automatically calibrate the dispense flow-rate of the fluid dispensing tool 130.

Image capturing (or video recording) with image (or video frame) analysis can also be used to measure and calibrate the dispense flow-rate during maintenance without the need for engineers or technicians to open the SPS tool in which the fluid dispensing tool 130 is included and measure it manually. This significantly reduces safety risks and losses in production due to tool down-time. Capturing (or recording) and analyzing images (or video frames) of SPS processing during production allows for real-time monitoring of dispense flow-rate and fault detection if the flow-rate is determined to have drifted too far. This can lead to better surface layer uniformity and repeatability and higher end-of-line (EOL) yield. It can also prevent excursions automatically detecting flow-rate faults and rapidly troubleshoot a fluid dispensing tool when dispense flow-rate is in question.

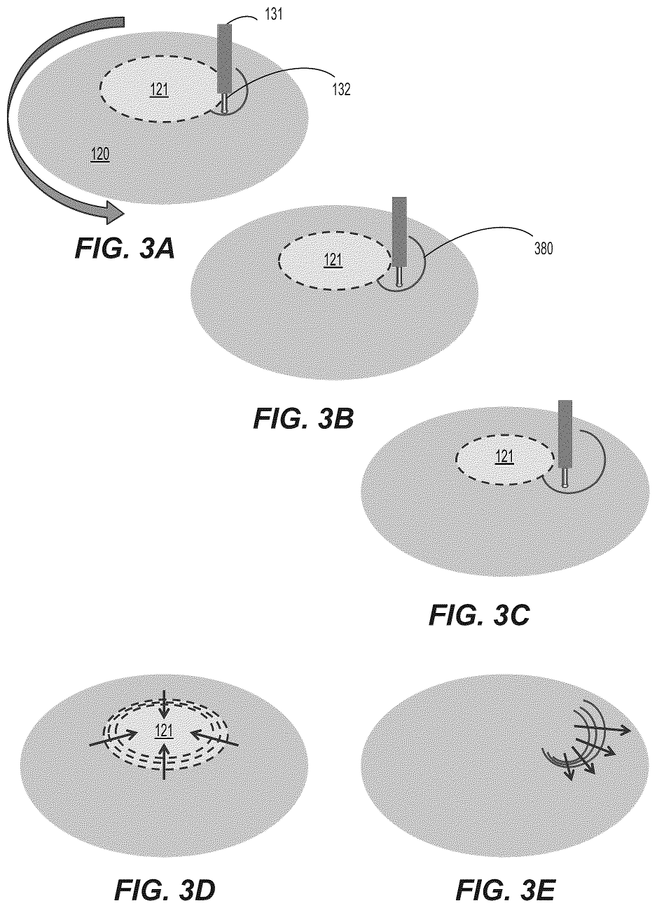

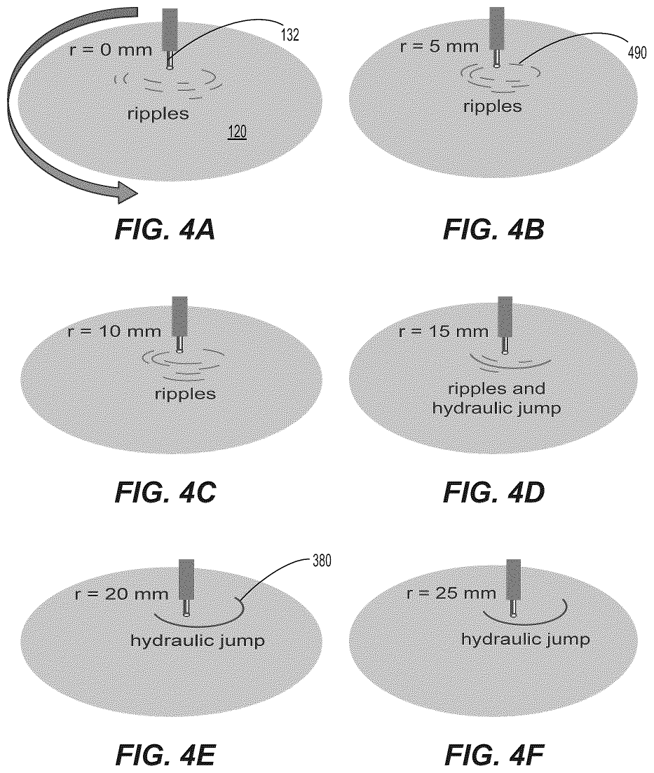

In an embodiment, various hydraulic features can be utilized for the calibration depending on the golden conditions. For example, when the dispenser arm 131 is positioned closer to the edge of the rotating wafer 120 (e.g., a radial distance ≥50 mm on a 300 mm diameter wafer), a centrifugal force prevents the fluid dispensed from the dispenser nozzle 132 from flowing towards the center of the wafer 120 and a dry spot 121 will remain in the center, as shown in FIGS. 3A-3C. Simultaneously, a hydraulic jump 380 or wave front will form under the dispenser nozzle 132 where the liquid stream impinges onto the wafer 120. As the dispense flow-rate increases, the area of the dry spot 121 in the center of the wafer 120 will decrease and the arc size of the hydraulic jump 380 will increase, as shown in FIGS. 3D and 3E. FIGS. 3A-3E are the appearance of the hydraulic features, e.g., the hydraulic jump 380, as viewed from the first camera 151, which is disposed in the top corner of the processing chamber 170 to view the fluid dispensed on the wafer 120 and capture the image of the fluid from an inclined angle, and, accordingly, the wafer 120 is shown having an elliptical shape and the dry spot 121 is not in the center of the wafer 120. If the dispenser nozzle 132 is moved closer to the center of the wafer (≤50 mm on a 300 mm diameter wafer), the fluid can flow over the entire wafer 120 and the dry spot 121 (shown in FIGS. 3A-3E) will disappear and the hydraulic jump 380 may also become thinner and less discernable, as shown in FIGS. 4D-4F. When the dispenser nozzle 132 is nearly in the center of the wafer (≤10 mm on a 300 mm diameter wafer), the hydraulic jump 380 will no longer be visible, but there will still be ripples 490 on the surface of the fluid, as shown in FIGS. 4A-4C.

To automatically quantify the hydraulic features (e.g., the hydraulic jump 380) described above, images (or videos) of the dispense can be captured (or recorded) during maintenance and production if the golden conditions are also used in the production recipe. Computer vision software can be used on each image (or video frame) along with image filters, image masks, and edge detection to quantify the location (x, y coordinates) and size (number of pixels) of the hydraulic features. The edge detection algorithms may incorporate Roberts, Sobel, Prewitt, Canny, and other methods, by reference to T. Lindeberg, Int. J. of Computer Vision 30 (1998), which is incorporated herein by reference in its entirety.

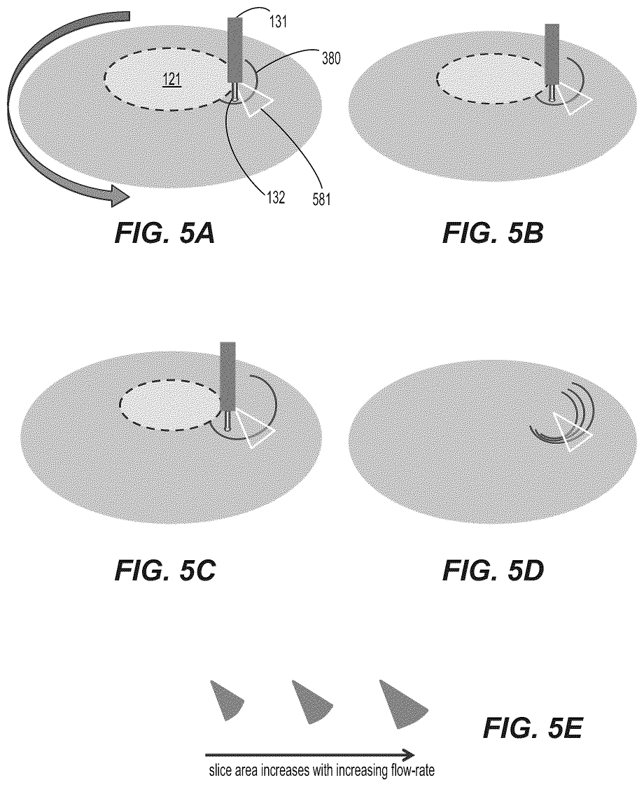

Different regions within the captured image (or video frame) can be used for direct comparison of hydraulic feature attributes (e.g., size and shape of hydraulic jump of the fluid and dry spot). If the dry spot 121 is present in the center of the wafer 120, image analysis can be used to calculate the ellipsoid area of the dry spot 121. In an embodiment, the arc length of the edge of the hydraulic jump 380 can also be calculated within an analysis region 581, as shown in FIGS. 5A-5D. In an embodiment, the analysis region 581 may be a triangular mask having a fixed size and location (x, y coordinates). The analysis region 581 should be large enough to intersect the edge of the hydraulic jump 380 for a range of dispense flow-rates. For each image (or video frame), a slice area can be defined as the area between the tip of the triangle and the edge of the hydraulic jump 380. As dispense flow-rate increases, the size of the slice area also increases, as shown in FIG. 5E, allowing enabling discernment of the flow-rate. In cases where the dispenser arm 131 is positioned close to the center of the wafer (≤10 mm on a 300 mm diameter wafer), it may be possible to compare the size and movement of ripples on the fluid surface.

As long as calibration (or reference) curves can be created for various hydraulic jump features, then changes in dispense flow-rate can be detected and re-calibration performed, even if the first-principles relationship between feature size on flow-rate cannot be calculated. The method 200 and the system 100 can detect changes in dispense flow-rate less than 0.40% using a camera with low resolution (VGA 640×480) and even smaller changes in flow-rate for higher resolution cameras.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A system, comprising:
an image capturing device configured to capture on a substrate a first image of a first fluid and a second image of a second fluid dispensed sequentially under a predetermined condition; and
an image analyzer coupled to the image capturing device, the image analyzer configured to compare the second image and the first image to determine whether a second dispense flow-rate at which the second fluid is dispensed is different from a first dispense flow-rate at which the first fluid is dispensed.

2. The system of claim 1, further comprising:
a fluid dispensing tool configured to dispense the first fluid and the second fluid,
wherein the image analyzer is further configured to calibrate the fluid dispensing tool after determining that the second dispense flow-rate is different from the first dispense flow-rate.

3. The system of claim 1, wherein the image analyzer is further configured to generate a first curve based on the first image and a second curve based on the second image, and determines whether the second dispense flow-rate is different from the first dispense flow-rate by comparing the second curve and the first curve, the first curve relates a first feature attribute of the first fluid to the first dispense flow-rate, and the second curve relates a second feature attribute of the second fluid to the second dispense flow-rate.

4. The system of claim 3, wherein the first feature attribute of the first fluid includes a first hydraulic feature of the first fluid, the second feature attribute of the second fluid includes a second hydraulic feature of the second fluid, and the image analyzer determines whether the second dispense flow-rate is different from the first dispense flow-rate by comparing the second hydraulic feature and the first hydraulic feature.

5. The system of claim 4, wherein the first hydraulic feature of the first fluid includes a first hydraulic jump of the first fluid or a first dry spot on the substrate, the second hydraulic feature of the second fluid includes a second hydraulic jump of the second fluid or a second dry spot on the substrate, and the image analyzer determines whether the second dispense flow-rate is different from the first dispense flow-rate by comparing the second hydraulic jump and the first hydraulic jump or comparing the second dry spot and the first dry spot.

6. The system of claim 5, wherein the predetermined condition includes an analysis region of the first and second images that overlaps the first and second hydraulic jumps, and the image analyzer determines whether the second dispense flow-rate is different from the first dispense flow-rate by determining whether a first length of a first arc of the first hydraulic jump within the analysis region is different from a second length of a second arc of the second hydraulic jump within the analysis region.

7. The system of claim 4, wherein the first hydraulic feature of the first fluid includes a first ripple feature of the first fluid, the second hydraulic feature of the second fluid includes a second ripple feature of the second fluid, and the image analyzer determines whether the second dispense flow-rate is different from the first dispense flow-rate by comparing sizes and/or movements of the first and second ripple features.

8. The system of claim 1, wherein the predetermined condition includes at least one selected from a group consisting of chemical contained in the first and second fluid, surface treatment being performed on the substrate, where the first fluid is dispensed and impinges the substrate, a rotating speed of the substrate, and a range of dispense flow-rates including the first and second dispense flow-rates.

9. The system of claim 1, wherein the second fluid is different from the first fluid.

10. The system of claim 1, wherein the second fluid is a same as the first fluid.

11. A method, comprising:
capturing on a substrate a first image of a first fluid and a second image of a second fluid dispensed sequentially under a predetermined condition; and
comparing the second image and the first image to determine whether a second dispense flow-rate at which the second fluid is dispensed is different from a first dispense flow-rate at which the first fluid is dispensed.

12. The method of claim 11, further comprising:
dispensing the first fluid and the second fluid on the substrate; and
adjusting the second dispense flow-rate after determining that the second dispense flow-rate is different from the first dispense flow-rate.

13. The method of claim 11, further comprising:
generating a first curve based on the first image and a second curve based on the second image,
wherein whether the second dispense flow-rate is different from the first dispense flow-rate is determined by comparing the second curve and the first curve, the first curve relates a first feature attribute of the first fluid to the first dispense flow-rate, and the second curve relates a second feature attribute of the second fluid to the second dispense flow-rate.

14. The method of claim 13, wherein the first feature attribute of the first fluid includes a first hydraulic feature of the first fluid, the second feature attribute of the second fluid includes a second hydraulic feature of the second fluid, and whether the second dispense flow-rate is different from the first dispense flow-rate is determined by comparing the second hydraulic feature and the first hydraulic feature.

15. The method of claim 14, wherein the first hydraulic feature of the first fluid includes a first hydraulic jump of the first fluid or a first dry spot on the substrate, the second hydraulic feature of the second fluid includes a second hydraulic jump of the second fluid or a second dry spot on the substrate, and whether the second dispense flow-rate is different from the first dispense flow-rate is determined by comparing the second hydraulic jump and the first hydraulic jump or by determining the second dry spot and the first dry spot.

16. The method of claim 15, wherein the predetermined condition includes an analysis region of the first and second images that overlaps the first and second hydraulic jumps, and whether the second dispense flow-rate is different from the first dispense flow-rate is determined by determining whether a first length of a first arc of the first hydraulic jump within the analysis region is different from a second length of a second arc of the second hydraulic jump within the analysis region.

17. The method of claim 14, wherein the first hydraulic feature of the first fluid includes a first ripple feature of the first fluid, the second hydraulic feature of the second fluid includes a second ripple feature of the second fluid, and whether the second dispense flow-rate is different from the first dispense flow-rate is determined by comparing sizes and/or movements of the first and second ripple features.

18. The method of claim 11, wherein the predetermined condition includes at least one selected from a group consisting of chemical contained in the first and second fluid, surface treatment being performed on the substrate, where the first fluid is dispensed and impinges the substrate, a rotating speed of the substrate, and a range of dispense flow-rates including the first and second dispense flow-rates.

19. The method of claim 11, wherein the second fluid is different from the first fluid,

20. The method of claim 11, wherein the second fluid is a same as the first fluid.
